(19) United States
(12) Patent Application Publication
(10) Pub. No.: US 2024/0222514 A1
(43) Pub. Date: Jul. 4, 2024

(54) ETCH STOP FOR OXIDE SEMICONDUCTOR DEVICES

(71) Applicant: Intel Corporation, Santa Clara, CA (US)

(72) Inventors: Christopher Connor, Portland, OR (US); Vishak Venkatraman, Portland, OR (US); Vladimir Nikitin, Portland, OR (US); Yasin Kaya, Hillsboro, OR (US)

(73) Assignee: Intel Corporation, Santa Clara, CA (US)

(21) Appl. No.: 18/090,056

(22) Filed: Dec. 28, 2022

(51) Int. Cl. H01L 29/786; H01L 27/12; H01L 29/66

(52) U.S. Cl. CPC H01L 29/7869; H01L 27/1225; H01L 29/66969; H01L 29/78618; H01L 29/78696

(57) ABSTRACT

An integrated circuit structure includes a first layer comprising a semiconductor material. In an example, the semiconductor material of the layer comprises an oxide semiconductor material (e.g., comprising a metal and oxygen). The integrated circuit structure further includes a second layer above the first layer, where the second layer includes a metal and one of oxygen or nitrogen (e.g., includes aluminum and oxygen). In an example, the second layer is an etch stop layer. In an example, the second layer has a thickness of at most 20 nanometers. The integrated circuit structure further includes a first source or drain terminal and a second source or drain terminal, where each of the first and second source or drain terminals extends through the second layer and is coupled to the first layer. In an example, the integrated circuit structure is a thin film transistor (TFT), where the first layer is a thin film channel structure of the TFT.

### FIELD OF THE DISCLOSURE

The present disclosure relates to integrated circuits, and more particularly, to integrated circuit devices comprising oxide semiconductor channel regions.

### BACKGROUND

A thin film transistor (TFT) includes a thin film layer comprising semiconductor material (such as oxide semiconductor material, or another appropriate semiconductor material), where the thin film acts as a channel region of the TFT. The TFT also includes source and drain terminals in contact with the thin film layer. A gate structure includes a gate electrode, and a gate dielectric that is between the gate electrode and the thin film.

Various TFT architectures may be possible. For example, in a bottom contact, top gate TFT architecture, the source or drain terminals are below the thin film and the gate structure is above the thin film. In a bottom contact, bottom gate TFT architecture, the source or drain terminals are below the thin film and the gate structure is also below the thin film. In a top contact, top gate TFT architecture, the source or drain terminals are above the thin film and the gate structure is also above the thin film. In a top contact, bottom gate TFT architecture, the source or drain terminals are above the thin film and the gate structure is below the thin film. A dual-gate TFT has a top gate and a bottom gate, and may similarly have the source or drain terminals above or below the thin film.

As integrated circuits, including TFT structures, continue to scale downward in size, a number of challenges arise. For example, with scaling, the thin film thickness reduces. There remain a number of non-trivial challenges with respect to forming TFT devices.

### BRIEF DESCRIPTION OF THE DRAWINGS

FIG. 1A illustrates a cross-sectional view of an integrated circuit structure that includes that includes (i) a layer comprising semiconductor material, (ii) an etch stop layer above the layer, (iii) a source or drain terminal that extends through the etch stop layer and lands on the semiconductor layer, (iv) another source or drain that extends through the etch stop layer and lands on the semiconductor layer, and (v) a backside gate structure comprising a gate electrode and gate dielectric below the layer of semiconductor material, in accordance with an embodiment of the present disclosure.

FIG. 1B illustrates a cross-sectional view of an integrated circuit structure that is at least in part similar to the integrated circuit structure of FIG. 1A, except that the etch stop layer spans above only sections (and not an entirety) of the semiconductor layer, in accordance with an embodiment of the present disclosure.

FIG. 2 illustrates a cross-sectional view of another integrated circuit structure that includes that includes (i) a layer of semiconductor material, (ii) an etch stop layer above at least some sections of the semiconductor layer, (iii) a source or drain terminal that extends through the etch stop layer and that lands on the semiconductor layer, (iv) another source or drain that extends through the etch stop layer and that lands on the semiconductor layer, and (v) a frontside gate structure comprising a gate electrode and gate dielectric above the layer, in accordance with an embodiment of the present disclosure.

FIG. 3 illustrates a cross-sectional view of a portion of an integrated circuit in which the integrated circuit structures of FIGS. 1A-2 may be used, in accordance with an embodiment of the present disclosure.

FIG. 4 illustrate a flowchart depicting a method of forming the example integrated circuit structures of FIGS. 1A-3, in accordance with an embodiment of the present disclosure.

FIGS. 5A, 5B, 5C, 5D, 5E, and 5F collectively illustrate an example integrated circuit structure (e.g., the integrated circuit structures of FIGS. 1A-2) in various stages of processing in accordance with the methodology of FIG. 4, in accordance with an embodiment of the present disclosure.

FIG. 6 illustrates a computing system implemented with integrated circuit structures (such as the integrated circuit structures illustrated in FIGS. 1A-3) formed using the techniques disclosed herein, in accordance with some embodiments of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

Integrated circuit structures are disclosed, which includes a device having a layer comprising a semiconductor material, an etch stop layer above the layer comprising the semiconductor material, and dielectric material above the etch stop layer, where a source terminal and a drain terminal extend through the dielectric material and the etch stop layer and land on the layer comprising the semiconductor material. In some examples, the device is a thin film device (TFT), where the layer comprising the semiconductor material forms a channel region of the TFT. In some such examples, the semiconductor material of the layer comprises an oxide semiconductor material (e.g., indium gallium zinc oxide, or IGZO), although other suitable TFT channel materials may be used as well.

In some examples, the etch stop layer is etch selective to the dielectric material. For example, an etch process to etch the dielectric material may not substantially etch the etch stop layer. In some such examples, the etch stop layer comprises an oxide or a nitride or a carbide or some combination, such as aluminum oxide or silicon nitride, or silicon carbide, or silicon oxycarbonitride, or other material that can be etched selectively with respect to the dielectric material. The etch stop layer comprising aluminum oxide (or another appropriate etch stop material) can be etch selective to the dielectric material of the device, for example. As described in detail herein in turn, in an example, the etch stop layer facilitates formation of recesses for the source or drain terminals of the device, without substantially damaging the layer comprising the semiconductor material. Numerous configurations and variations will be apparent in light of this disclosure.

### General Overview

As mentioned herein above, there remain a number of non-trivial challenges with respect to forming TFT devices. For example, in a top contact TFT architecture, the source and drain terminals are above a layer comprising a semiconductor material, where the layer forms a channel region of the device. In an example, with scaling, a thickness of the channel layer reduces. Prior to formation of the source and drain terminals, a dielectric material is deposited above the channel layer. To form the source and drain terminals landing on the channel layer, a first recess (where the source terminal is to be eventually formed) and a second recess (where the drain terminal is to be eventually formed) are formed to extend through the dielectric material, where the first and second recesses land on the channel layer. Because of relatively higher thickness of the dielectric material (which can range in tens of nanometers), a relatively harsh or aggressive etch process has to be employed to form the first and second recesses through the dielectric material. When the recesses land on the channel layer, such an aggressive etch process may damage the channel layer. Furthermore, with scaling of the devices, a thickness of the channel layer may already be relatively less (example thickness range discussed herein in turn). Accordingly, such damage to the channel layer may impact device performance, and/or may result in stoichiometric changes to the channel layer. For example, any damage to the TFT channel layer may result in gate leakage, bias temperature instability, and/or may even result in device failure.

Accordingly, techniques are described herein to form integrated circuit structures having a channel layer comprising a semiconductor material, and etch stop layer above the channel layer comprising the semiconductor material, a dielectric material above the etch stop layer, and a source terminal and a drain terminal extending through the dielectric material and the etch stop layer, to land on the channel layer. In an example, the etch stop layer facilitates formation of recesses for the source and drain terminals, without causing any damage, or reducing any damage, to the semiconductor material of the channel layer.

In some examples, the integrated circuit structure discussed herein is a TFT. In some such examples, the channel layer comprising the semiconductor material is a thin film channel layer that includes an oxide semiconductor, although any other semiconductor material suitable for TFT channel layer may also be used.

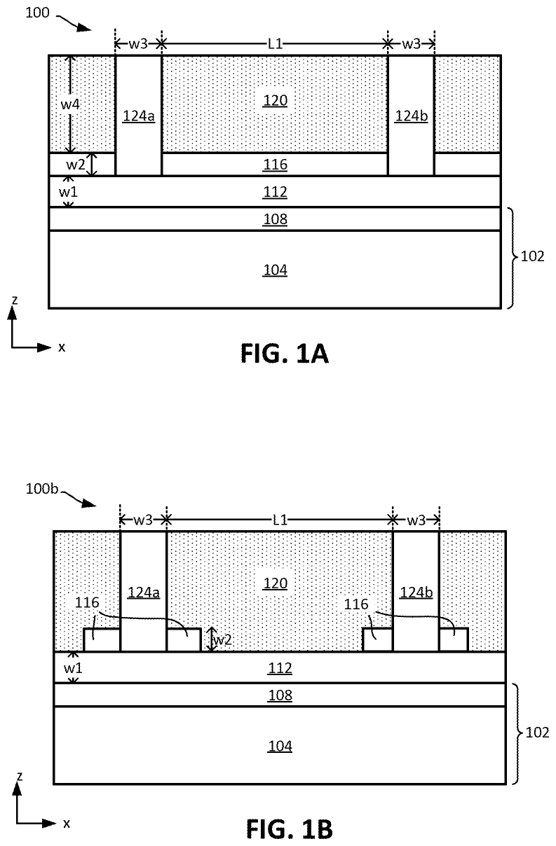

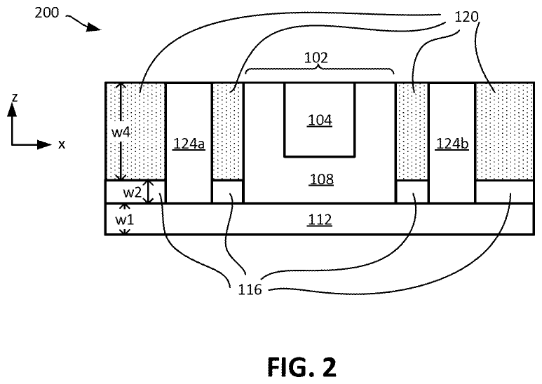

In some such examples, the source terminal and the drain terminal are above the channel layer, and thus, the TFT comprises a top contact TFT architecture. A gate structure of the TFT comprises a gate electrode, and gate dielectric that separates the gate electrode form the channel layer. In one example, the gate structure is below the channel layer (e.g., as illustrated in FIGS. 1A and 1B, for a top-contact, bottom gate TFT architecture). In another example, the gate structure is above the channel layer (e.g., as illustrated in FIG. 2, for a top-contact, top gate TFT architecture).

In one embodiment, the etch stop layer is etch selective to the dielectric material. For example, an etch process to etch the dielectric material may not substantially etch the etch stop layer. Accordingly, the etch stop layer is elementally and/or compositionally different from the dielectric material. The etch stop layer comprises an appropriate dielectric material, such as an appropriate oxide, nitride, carbide, or another appropriate dielectric material used for an etch stop layer. In an example, the etch stop layer comprise an oxide or a nitride, such as aluminum oxide (Al₂O₃). For example, the etch stop layer comprising aluminum oxide (or another etch stop material) can be etch selective to a dielectric material of silicon oxide or silicon nitride, for example.

The etch stop layer has a thickness w2 (e.g., see FIG. 1A) between the channel layer and the dielectric material, where the thickness w2 of the etch stop layer may be in the range of 1 to 20 nm, such as in the subrange of 1 to 15 nm, or 1 to 10 nm, or 5 to 10 nm, or 5 to 20 nm, or 10-20 nm, for example. The dielectric material has a height or thickness of w4 (e.g., se FIG. 1A), where w4 and w2 are measured in the same Z-axis or vertical direction, e.g., perpendicular to a length of the channel layer and perpendicular to a length of the etch stop layer. In some examples, w4 is at least 20 nm, or at least 25 nm, or at least 30 nm, or at least 35 nm, or at least 40 nm, or at least 50 nm, or at least 60 nm. In some such examples, w4 is greater than w2 by at least 2 nm, or at least 5 nm, or at least 7 nm, or at least 10 nm, or at least 20 nm, or at least 25 nm.

In some examples (such as that illustrated in FIG. 1A), the etch stop layer may span an entire length of the channel layer. In some other examples (such as those illustrated in FIGS. 1B and 2), the etch stop layer may span only sections, but not an entire length of the channel layer.

In an example, the etch stop layer facilitates formation of recesses for the source and drain terminals, without causing any damage, or reducing any damage, to the channel layer. A recess for a source or drain terminal extends through the dielectric material and the etch stop layer, and the source or drain contact is formed within the recess. In one embodiment, the recess for the source or drain terminal is formed using two distinct etch processes, such as (i) a first etch process that forms the recess extending through the dielectric material, but not substantially through the etch stop layer, and (ii) a second etch process that extends the recess through the etch stop layer and makes the recess land on the channel layer.

In an example, different etch chemistry (e.g., different etchants) may be used for the first and second etch processes. As an example, one of the first or second etch processes may use a dry etch process, and the other of the first or second etch processes may use a wet etch process. In another example, both first and second etch processes may use dry etch processes, or wet etch processes.

In an example, the first etch process may use relatively harsher or aggressive etch chemistry, as this etch process has to traverse through the relatively greater thickness w4 of the dielectric material. In contrast, the second etch process may use relatively gentler etch chemistry, as this etch process has to traverse through only the relatively smaller thickness w2 of the etch stop layer. Because the second etch process for landing on the channel layer is relatively gentle, the second etch process makes no damage (or reduces any damage) to the channel layer, when the recess eventually lands on the channel layer. Thus, the etch stop layer facilitates in implementing the two distinct etch processes, thereby preventing or at least reducing possibilities of damages to the channel layer during formation of the recess.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

It should be readily understood that the meaning of “above” and “over” in the present disclosure should be interpreted in the broadest manner such that “above” and “over” not only mean “directly on” something but also include the meaning of over something with an intermediate feature or a layer therebetween. As used herein, the term “backside” generally refers to the area beneath one or more semiconductor devices (below the device layer) either within the device substrate or in the region of the device substrate (in the case where the bulk of the device substrate has been removed). Note that the backside may become a frontside, and vice-versa, if a given structure is flipped. To this end, and as will be appreciated, the use of terms like “above” “below” “beneath” “upper” “lower” “top” and “bottom” are used to facilitate discussion and are not intended to implicate a rigid structure or fixed orientation; rather such terms merely indicate spatial relationships when the structure is in a given orientation.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For example, in some embodiments, such tools may be used to detect an integrated circuit structure comprising (i) a layer comprising semiconductor material, (ii) an etch stop layer above the layer, (iii) a source or drain terminal that extends through the etch stop layer and that is coupled to the layer, (iv) another source or drain that extends through the etch stop layer and that is coupled to the layer, and (v) a gate structure comprising a gate electrode and gate dielectric, where the gate structure is either below or above (e.g., depending on the implementation of the integrated circuit structure) the layer. In some examples, the integrated circuit structure is a TFT device. In some such examples, the semiconductor material of the layer is an oxide semiconductor material, and/or the etch stop layer comprises an oxide (such as aluminum oxide). Numerous configurations and variations will be apparent in light of this disclosure.

### Architecture

FIG. 1A illustrates a cross-sectional view of an integrated circuit structure 100 (also referred to herein as structure 100) that includes that includes (i) a layer 112 comprising semiconductor material, (ii) an etch stop layer 116 above the layer 112, (iii) a source or drain terminal 124a that extends through the etch stop layer 116 and that is coupled to the layer 112, (iv) another source or drain 124b that extends through the etch stop layer 116 and that is coupled to the layer 112, and (v) a gate structure 102 comprising a gate electrode 104 and gate dielectric 108 below the layer 116 of semiconductor material, in accordance with an embodiment of the present disclosure.

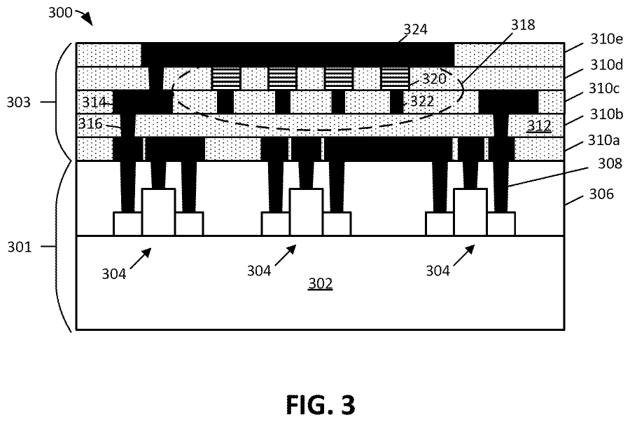

In some embodiments, the structure 100 is a thin film transistor (TFT), e.g., includes a thin film layer (such as the layer 112) that forms a channel region of the TFT. TFTs are a class of field-effect transistors (FETs) in which the channel material may be deposited as a thin film, rather than a monocrystalline material. A TFT comprises a thin film channel layer (such as the layer 112), a gate electrode (e.g., the gate electrode 104), and source and drain terminals (e.g., terminals 124a, 124b), over a supporting but non-conducting substrate (the substrate is not illustrated in FIG. 1A, but illustrated in FIG. 3 described herein below).

In some embodiments, the structure 100 comprises the layer 112 comprising semiconductor material. The layer 112, in an example, is a thin film configured to act as a channel layer of the TFT structure. As illustrated, the layer 112 has a height or thickness of w1, where the thickness w1 is measured in a Z-axis or vertical direction, e.g., perpendicular to a direction of a length of the layer 112. In an example, the thickness w1 is in the range of 5-25 nm, e.g., in a sub-range of 5-8 nm, or a sub-range of 5-15 nm, or a sub-range of 5-20 nm, or a sub-range of 10-15 nm, or a sub-range of 10-20 nm, or a sub-range of 10-25 nm, or a sub-range of 15-20 nm, or a sub-range of 15-25 nm, for example.

A length of the layer 112 between the source or drain terminals 124a and 124b is L1, as illustrated in FIG. 1A. In an example, length L1 is measured between a wall of the source or drain terminal 124a facing the source or drain terminal 124b, and a wall of the source or drain terminal 124b facing the source or drain terminal 124a, as illustrated. In an example, the length L1 is in the range of 20 to 80 nm, such as in the subrange of 20-60 nm, or 20-40 nm, or 30-80 nm, or 30-70 nm, or 30-50 nm, or 40-70 nm, for example.

While layer 112 may have any composition known to be suitable as a TFT channel material, such as a group IV material (e.g., Si, Ge, SiGe), in some embodiments the layer 112 may be an oxide semiconductor. An oxide semiconductor is a semiconducting oxide. In an example, oxide semiconductors can be used for low temperature transistor fabrication, and can offer high carrier mobility and a tunable material band gap and resistivity. Examples include metal oxides with a transition metal (e.g., IUPAC group 4-10) or post-transition metal (e.g., IUPAC groups 11-15). In some embodiments, the metal oxide includes at least one of Mg, Cu, Zn, Sn, Ti, Ni, Ga, In, Sb, Sr, Cr, Co, V, or Mo, and oxygen. The metal oxides may be suboxides (A2O), monoxides (AO), binary oxides (AO2), ternary oxides (ABO3), and mixtures thereof. In some embodiments, the layer 112 comprises a tin oxide (SnOx), such as Tin (IV) oxide, or SnO2. In other embodiments, the tin oxide is Tin (II) oxide (SnO) or a mixture of SnO and SnO2, where x may range between 1 and 2. While the range of x may be expanded, semiconducting properties may be lost (e.g., the material becomes a pure conductor if x is to low, and a pure insulator if x is too high). In some other embodiments, semiconductor thin film 202c may comprise a zinc oxide (ZnOx), such as Zn(II) oxide, or ZnO. In other embodiments, the zinc oxide is zinc peroxide (ZnO2) or a mixture of ZnO and ZnO2, where x may range between 1 and 2. In some other embodiments, semiconductor thin film 202c comprises titanium oxide (TiOx), or SnOx. The layer 112 may be a p-type, n-type, or intrinsic material. Example oxide semiconductors that may have suitable p-type conductivity include copper oxide (CuOx). In some CuOx embodiments, the layer 112 comprises Cu(I) oxide, or Cu2O. In other embodiments, the layer 112 is Cu(II) oxide (CuO) or a mixture of CuO and Cu2O, where x may range between 0.5 and 1. In another example, the layer 112 comprises include NiOx.

The layer 112 may be intentionally doped, or not. Compared to intrinsic oxide semiconductor that is not intentionally doped, n-type and p-type oxide semiconductors may have a higher concentration of impurities, such as, but not limited to, one or more group III element, group V element, and/or elemental hydrogen (H). Dopant levels in the layer 112 may be selected to arrive at optimal threshold voltage associated with gating the oxide semiconductor within the channel region and/or for lowest bulk and/or junction resistance within the source or drain terminals. The layer 112 may comprise ZnOx doped with In and Ga, for example. While semiconductor oxides may display some level of structural ordering (e.g., nanocrystallinity), in some embodiments amenable to lowest processing temperatures, the layer 112 may be in an amorphous state.

In some embodiments, the layer 112 may include material comprising amorphous silicon, zinc oxide, amorphous germanium, polysilicon, poly germanium doped with boron, poly germanium doped with aluminum, poly germanium doped with phosphorous, poly germanium doped with arsenic, indium oxide, tin oxide, gallium oxide, indium gallium zinc oxide (IGZO), copper oxide, nickel oxide, cobalt oxide, indium tin oxide, tungsten disulphide, molybdenum disulphide, molybdenum selenide, black phosphorus, indium antimonide, graphene, graphyne, borophene, germanene, silicene, Si2BN, stanene, phosphorene, molybdenite, poly-III-V like InAs, InGaAs, InP, amorphous InGaZnO (a-IGZO), crystal-like InGaZnO (c-IGZO), GaZnON, ZnON, and/or C-Axis Aligned Crystal (CAAC) InGaZnO, for example.

In some embodiments, the structure 100 further comprises the source or drain terminals 124a and 124b. In an example, the terminal 124a acts as one of a source terminal or a drain terminal, and the terminal 124b acts as the other of the source terminal or the drain terminal, based on an application of the structure 100 or configuration of the circuit for which the structure 100 is being used.

As illustrated, the source or drain terminal 124a (or source or drain terminal 124b) has a diameter or width of w3 measured in the X-axis direction, e.g., in the direction of the length of the channel 112. In an example, the width w3 is in the range of 10 to 60 nm, such as in the subrange of 10-50 nm, or 10-40 nm, or 10-25 nm, or 20-60 nm, or 20-40 nm, or 20-30 nm, or 30-60 nm, or 30-50 nm, or 40-60 nm, for example.

In an example, the source or drain terminals 124a, 124b comprises metal or metal alloy that, when interfacing the chosen oxide semiconductor of the layer 112 will, either as deposited, or upon subsequent annealing, have suitable contact resistance. In an example, source or drain terminals 124a, 124b may have a relatively low affinity for oxygen to limit gettering oxygen from the layer 112. In some embodiments, the source or drain terminals 124a, 124b include a metal nitride at the interface of (e.g., in direct contact with) the layer 112. Metal nitrides offer good stability and do not ready oxidize. Example metal nitrides include TiN, TaN, and WN. In other embodiments, the source or drain terminals 124a, 124b include a noble metal (e.g., Pt) at the interface of (e.g., in direct contact with) the layer 112.

In some embodiments, the layer 112 is above a gate stack 102 comprising agate electrode 104 and a gate dielectric 108. The gate dielectric 108 separates the layer 112 from the gate electrode 104.

The gate dielectric 108 may include a single material layer or multiple stacked material layers. In some embodiments, gate dielectric 108 includes a first dielectric layer such as silicon oxide, and a second dielectric layer that includes a high-K material such as hafnium oxide. The hafnium oxide may be doped with an element to affect the threshold voltage of the given semiconductor device. According to some embodiments, the doping element used in gate dielectric 108 is lanthanum.

In an example, the gate electrode 104 may include any sufficiently conductive material, such as a metal, metal alloy, or doped polysilicon. In an example, the gate electrode 104 may include an elemental metal layer, a metal alloy layer, or laminate structure of either or both. In some embodiments, the gate electrode 104 may be a metal nitride, such as TiN (e.g., with a work function of 4.0-4.7 eV). The gate electrode 104 may also comprise Al (e.g., TiAlN). Other alloy constituents may also be employed, such as, but not limited to C, Ta, W, Pt, and Zn. The combination of gate dielectric 108 and gate electrode 104 forms the gate structure 102.

In one embodiment, an etch stop layer 116 is above the layer 112, and dielectric material 120 is above the etch stop layer 116. The etch stop layer 116 is above the layer 112, spanning a length of the layer 112 in the example of FIG. 1A. As illustrated, the source or drain terminals 124a, 124b extend through the dielectric material 120 and the etch stop layer 116, to make contact with the layer 112.

In an example, the etch stop layer 116 has a height or thickness of w2 between the layer 112 and the dielectric material 120. As illustrated, the thicknesses w1 and w2 are measured in the same Z-axis or vertical direction, e.g., perpendicular to the length of the layer 112 and perpendicular to the length of the etch stop layer 116. In an example, the thickness w2 is in the range of 1 to 20 nm, such as in the subrange of 1 to 15 nm, or 1 to 10 nm, or 5 to 10 nm, or 5 to 20 nm, or 10-20 nm in an example.

In an example, the etch stop layer 116 is etch selective to the dielectric material 120. For example, an etch process to etch the dielectric material 120 may not substantially etch the etch stop layer 116. Accordingly, the etch stop layer 116 is elementally and/or compositionally different from the dielectric material 120. The etch stop layer 116 comprises an appropriate dielectric material, such as an appropriate oxide, nitride, carbide, or another appropriate dielectric material used for an etch stop layer. In an example, the etch stop layer 116 comprise an oxide or a nitride, such as aluminum oxide (Al₂O₃) in an example. For example, the etch stop layer 116 comprising aluminum oxide (or another appropriate oxide or a nitride) can be etch selective to the dielectric material 120.

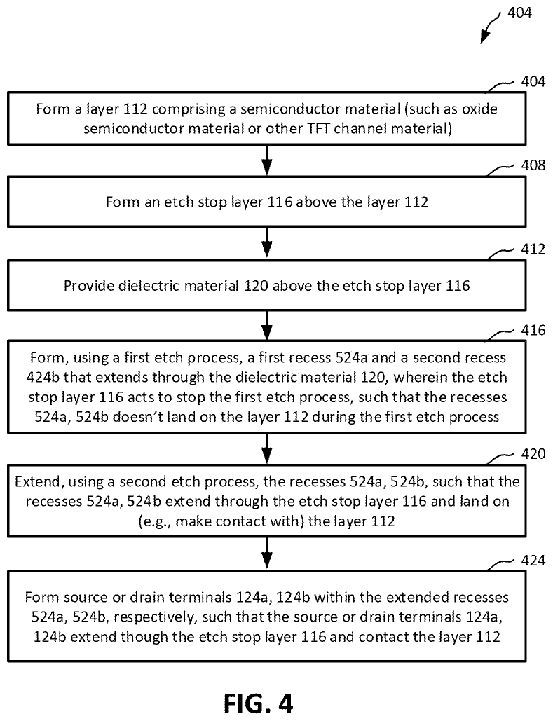

As described in detail herein in turn (e.g., with respect to processes 416 and 420 of method 400 of FIG. 4), in an example, the etch stop layer 112 is to facilitate formation of recesses for the source or drain terminals 124a, 124b, without substantially damaging the layer 112.

The dielectric material 120 above the etch stop layer 116 may be any appropriate dielectric material, such as an appropriate oxide, nitride, carbide, oxynitride, oxycarbide, or oxycarbonitride, for example. In an example, the dielectric material 120 (or at least a part of the dielectric material 120) may act as a channel passivation layer for the layer 112. As illustrated, the dielectric material 120 has a height or thickness of w4, where w1, w2, and w4 are measured in the same Z-axis or vertical direction, e.g., perpendicular to the length of the layer 112 and perpendicular to the length of the etch stop layer 116. In an example, w4 is at least 20 nm, or at least 25 nm, or at least 30 nm, or at least 35 nm, or at least 40 nm, or at least 50 nm, or at least 60 nm. In such an example, w4 is greater than w2 by at least 2 nm, or at least 5 nm, or at least 7 nm, or at least 10 nm, or at least 20 nm, or at least 25 nm.

In FIG. 1A, the etch stop layer 112 spans substantially an entire length of the layer 112. However, in one example, the etch stop layer 116 may be on only some, but not all, sections of the layer 112. For example, FIG. 1B illustrates a cross-sectional view of an integrated circuit structure 100b (also referred to herein as structure 100b) that is at least in part similar to the integrated circuit structure 100 of FIG. 1A, where in the integrated circuit structure 100b of FIG. 1B, the etch stop layer 116 spans above only sections (and not an entirety) of the layer 112, in accordance with an embodiment of the present disclosure.

For example, the etch stop layer 116 is above a section of the layer 112 that is proximal to the source or drain terminal 124a, and also above another section of the layer 112 that is proximal to the source or drain terminal 124b. As described herein in turn, the etch stop layer 112 is to facilitate formation of recesses for the source or drain terminals 124a, 124b, without substantially damaging the layer 112. Thus, in FIG. 1B, the etch stop layer 112 is only on or near those sections of the layer 112, on which the source or drain terminals 124a, 124b are formed, and not necessarily on other sections of the layer 112 on which the source or drain terminals 124a, 124b are not to be formed.

FIGS. 1A and 1B illustrate back gated TFT architectures (e.g., top contact, bottom gate TFT architectures), where the source or drain terminals 124a, 124b are above the layer 112, and the gate structure 102 is below the layer 112. However, teachings of this disclosure may also be applied to other appropriate TFT configuration as well, e.g., where the source or drain terminals 124a, 124b (e.g., extending through the etch stop layer 116) and the gate structure 102 are both above the channel layer 112. For example, FIG. 2 illustrates a cross-sectional view of another integrated circuit structure 200 (also referred to herein as structure 200) that includes that includes (i) a layer 112 of semiconductor material, (ii) an etch stop layer 116 above at least some sections of the layer 112, (iii) a source or drain terminal 124a that extends through the etch stop layer 116 and that is coupled to the layer 112, (iv) another source or drain 124b that extends through the etch stop layer 116 and that is coupled to the layer 112, and (v) a gate structure 102 comprising a gate electrode 104 and gate dielectric 108 above the layer 116, in accordance with an embodiment of the present disclosure.

Similar components in the structures 100 and 200 of FIGS. 1A and 2, respectively, are labelled using the same labels. In the structure 100 of FIG. 1A, the gate structure 102 is below the layer 112, and the structure 100 is a top contact, bottom gate TFT architecture. In contrast, in the structure 200 of FIG. 2, the gate structure 102 is above the layer 112, and the structure 200 is a top contact, top gate TFT architecture.

In FIG. 2, similar to FIG. 1B, the etch stop layer 116 may not span an entire length of the layer 112. Thus, in the structure 200 of FIG. 2, the etch stop layer 116 is above sections of the layer 112, such that the source or drain terminals 124a, 124b extend through the dielectric material 120 and through the etch stop layer 116, to land on the layer 112. The gate dielectric 108 may be on another section of the layer 112 that is not occupied by the etch stop layer 116.

FIG. 3 illustrates a cross-sectional view of a portion of an integrated circuit 300 in which the integrated circuit structures of FIGS. 1A-2 may be used, in accordance with an embodiment of the present disclosure. According to some embodiments, the integrated circuit 300 includes a device region 301, and an interconnect region 303 over the device region 301. Device region 301 includes, for example, a plurality of semiconductor devices 304 along with one or more other layers or structures associated with the semiconductor devices 304. The semiconductor devices 304 in this example are non-planar metal oxide semiconductor (MOS) transistors, such as tri-gate or gate-all-around (GAA) transistors, although other transistor topologies and types can also benefit from the techniques provided herein, as will be appreciated (e.g., planar transistors, thin film transistors, or any other transistors to which contact can be made).

In some examples, device region 301 includes a substrate 302 and one or more dielectric layers 306 that surround active portions of the semiconductor devices 304 (e.g., logic or compute transistors, input/output transistors, and/or radio frequency transistors). Device region 301 may also include one or more conductive contacts 308 that provide electrical contact to transistor elements such as gate structures, drain regions, or source regions. Conductive contacts 308 may include, for example, tungsten, ruthenium, or copper, although other metal or metal alloy materials are possible.

Substrate 302 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, backside processing is used to remove substrate 302 and form additional backside interconnect layers.

Interconnect region 303 includes a plurality of interconnect layers 310a-310e stacked over one another. Each interconnect layer can include a dielectric material 312 along with one or more different conductive features, active devices, and/or passive devices. Dielectric material 312 can be any dielectric, such as silicon oxide, silicon oxycarbide, silicon nitride, or silicon oxynitride. Dielectric material 312 may be formed using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include any number of conductive traces 314 and conductive vias 316 arranged in any pattern across the interconnect layers 310a-310e to carry signal and/or power voltages to/from the various semiconductor devices 304. As used herein, conducive vias, such as conductive via 316, extend at least partially through an interconnect layer to connect between conductive traces on an upper interconnect layer and/or a lower interconnect layer, while conductive contacts, such as conductive contact 308, extend at least partially through a portion of dielectric layer 306 to contact one or more transistor elements. Although interconnect region 303 is illustrated with only five interconnect layers, any number of interconnect layers can be used within interconnect region 303. Interconnect layers are sometimes called metallization layers (e.g., such as M0 through M15).

Any of conductive traces 314 and conductive vias 316 can include any number of conductive materials, with some examples including copper, ruthenium, tungsten, cobalt, molybdenum, titanium, tantalum, and alloys thereof. In some cases, any of conductive traces 314 and conductive vias 316 include a relatively thin liner or barrier, such as manganese, ruthenium, titanium nitride, titanium silicide, tungsten carbo-nitride (WCN), physical vapor deposited (PVD) or ALD tungsten, tantalum, or tantalum nitride, to name a few examples.

Note that each of the various conductive vias 316 and conductive contacts 308 are shown with tapered profiles to indicate a more natural appearance due to the etching process used to form the openings, although such tapering may not always be present. Any degree of tapering may be observed depending on the etch parameters used and the thickness of the dielectric layer being etched through. Furthermore, conductive vias may be stacked one over the other through different dielectric layers of interconnect region 303. However, in some examples, a single via recess may be formed through more than one dielectric layer yielding a taller, more tapered conductive via that extends through two or more dielectric layers (e.g., a deep via or supervia).

As can be further seen in this example embodiment, interconnect region 303 also includes a memory array 318 having any number of backend memory structures. Memory array 318 may extend vertically across any number of interconnect layers (e.g., one, two or many). In some embodiments, memory array 318 includes a plurality of memory cells 320 sandwiched between first conductive layers 322 extending in a first direction and a second conductive layer 324 extending in a second direction. First conductive layers 322 may be parallel wordlines extending into and out of the page as part of interconnect layer 310c. Second conductive layer 324 may be one layer of several parallel bitlines as part of interconnect layer 310e that extend orthogonally to first conductive layers 322. This example shows memory cells 320 contained within interconnect layer 310d, but other embodiments may have a memory cell that extends vertically through two or more such interconnect layers.

As noted above, memory cells 320 can include any number of layers to form a given memory structure, such as a TFT memory cell. For example, any of the TFT structures 100, 100b, or 200 of FIGS. 1A-2 may be used within the memory cells 320 of FIG. 3.

Although FIG. 3 illustrates an application of a TFT structure within a memory cell, the TFT structures 100, 100b, or 200 of FIGS. 1A-2 may be used for any other appropriate application as well, such as to form logic transistors within the interconnect region 303. Thus, in an example, the TFT structures 100, 100b, or 200 of FIGS. 1A-2 may be within the interconnect region 303, and above the device region 301, and may be formed on a non-conductive supporting substrate, such as the dielectric material 312.

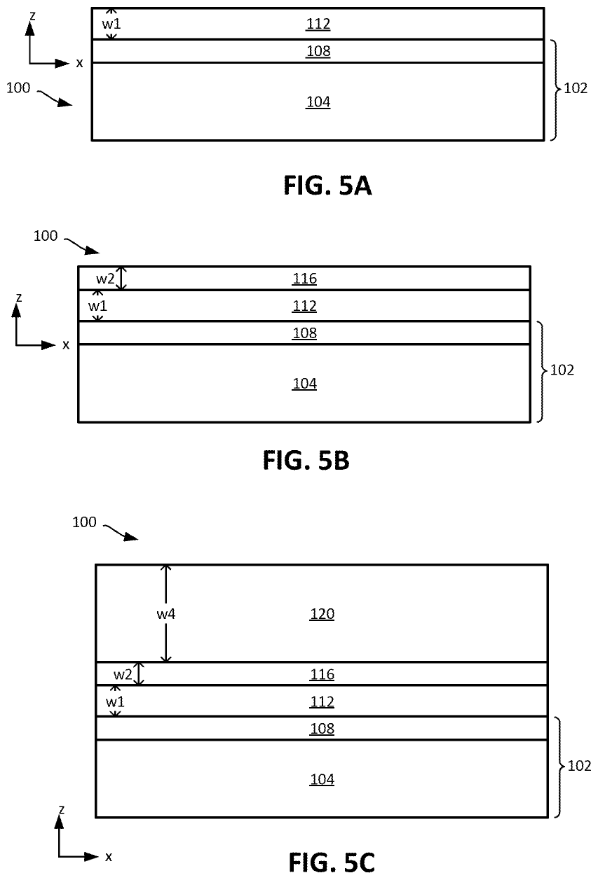

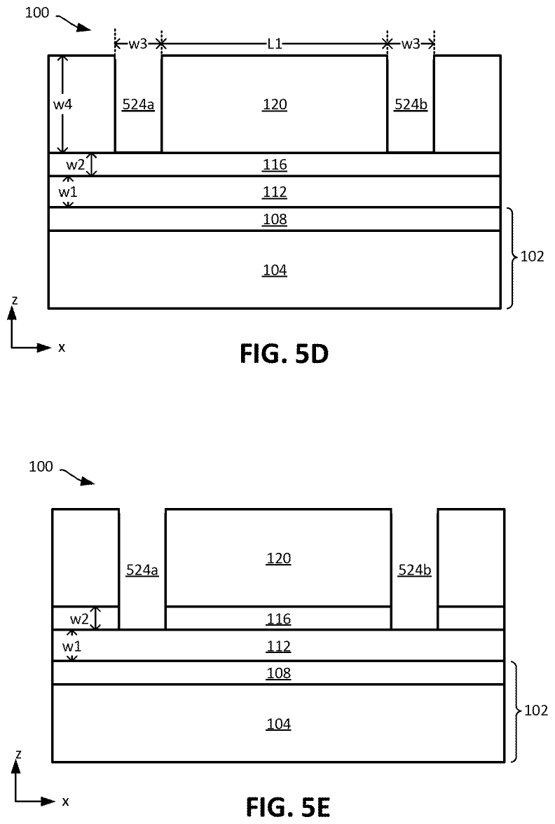

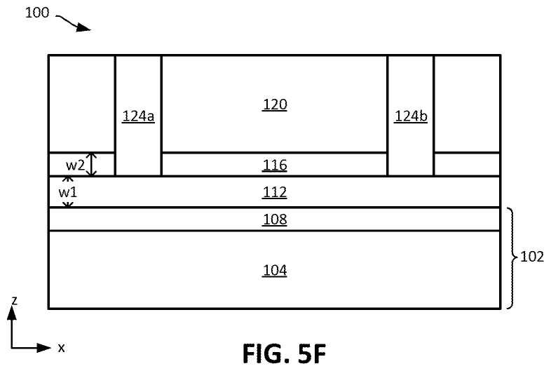

FIG. 4 illustrate a flowchart depicting a method 400 of forming the example integrated circuit structures of FIGS. 1A-3, in accordance with an embodiment of the present disclosure. FIGS. 5A, 5B, 5C, 5D, 5E, and 5F collectively illustrate an example integrated circuit structure (e.g., the integrated circuit structures of FIGS. 1A-2) in various stages of processing in accordance with the methodology 400 of FIG. 4, in accordance with an embodiment of the present disclosure. FIGS. 4 and 5A-5F will be discussed in unison.

Referring to FIG. 4, the method 400 includes, at 404, forming a layer 112 comprising a semiconductor material (such as oxide semiconductor material or other TFT channel material), e.g., as illustrated in FIG. 5A. In the example of FIG. 5A, the layer 112 is formed above the gate structure 102 comprising the gate electrode 104 and the gate dielectric 108. In an example, the thin film layer 112 may be deposited on the gate structure 102 using an appropriate deposition process, such as chemical vapor deposition (CVD), atomic layer deposition (ALD), sputtering, or spray coating.

FIG. 5A corresponds to the structures 100 and 100b of FIGS. 1A and 1, where the channel layer 112 is above the gate structure 102. However, if the structure 200 of FIG. 2 is to be formed, the channel layer 112 may be formed above an appropriate supporting substrate (such as a non-conducting supporting substrate, in an example).

Referring again to the method 400 of FIG. 4, the method 400 then proceeds from 404 to 408. At 408, an etch stop layer 116 is formed above the layer 112, e.g., as illustrated in FIG. 5B.

FIG. 5B is for formation of the structure 100 of FIG. 1A, in which the etch stop layer 116 spans an entire length of the layer 112. However, if formation of the structure 100b of FIG. 1B (or the structure 200 of FIG. 2) is desired, the etch stop layer 116 may be on sections, but not entirety, of the layer 112.

The etch stop layer 116 comprises an appropriate dielectric material, such as an appropriate oxide, nitride, carbide, or another appropriate dielectric material used for an etch stop layer. In an example, the etch stop layer 116 comprise an oxide, such as aluminum oxide (Al₂O₃), to make the etch stop layer 116 etch selective with respect to the dielectric material 120. The etch stop layer 116 may be deposited using an appropriate deposition technique, such as CVD, physical vapor deposition (PVD), ALD, vapor-phase epitaxy (VPE), molecular beam epitaxy (MBE), or liquid-phase epitaxy (LPE), for example.

Referring again to the method 400 of FIG. 4, the method 400 then proceeds from 408 to 412. At 412, dielectric material 120 is provided above the etch stop layer 116, e.g., as illustrated in FIG. 5C.

FIG. 5C is for formation of the structure 100 of FIG. 1A, in which the dielectric material is above an entirety of the etch stop layer 116. If formation of the structure 200 of FIG. 2 is desired, the dielectric material 120 may be on the etch stop layer 116, and a gate structure 102 may be formed between two sections of the dielectric material 120.

The dielectric material 120 may be any appropriate dielectric material, such as an appropriate oxide, nitride, carbide, oxynitride, oxycarbide, or oxycarbonitride, for example. In an example, the etch stop layer 116 is etch selective to the dielectric material 120. For example, an etch process to etch the dielectric material 120 may not substantially etch the etch stop layer 116. Accordingly, the etch stop layer 116 is elementally and/or compositionally different from the dielectric material 120, in an example. The dielectric material 120 may be deposited on the etch stop layer 116 using an appropriate deposition technique, such as CVD, PVD, ALD, VPE, MBE, or LPE, for example.

Referring again to the method 400 of FIG. 4, the method 400 then proceeds from 412 to 416. At 416, using a first etch process, a first recess 524a and a second recess 524b are formed, as illustrated in FIG. 5D. As also illustrated in FIG. 5D, the recesses 524a, 524b extend through the dielectric material 120, and the etch stop layer 116 acts to stop the first etch process, such that the recesses 524a, 524b doesn't extend through the etch stop layer 116 and doesn't land on the layer 112 during the first etch process. In one example, the recesses 524a, 524b may extend partially through the etch stop layer 116, but may not extend fully through the etch stop layer 116. In another example, the recesses 524a, 524b may not substantially extend though the etch stop layer 116.

Referring again to the method 400 of FIG. 4, the method 400 then proceeds from 416 to 420. At 420, using a second etch process, the recesses 524a, 524b are further extended, such that the recesses 524a, 524b extend through the etch stop layer 116 and land on (e.g., make contact with) the layer 112, as illustrated in FIG. 5E.

Thus, the recesses 524a, 524b of FIG. 5E are formed using two distinct etch processes, such as (i) the first etch process of 416 that forms the recesses extending through the dielectric material 120, but not substantially through the etch stop layer 116, and (ii) the second etch process of 420 that extends the recesses through the etch stop layer 116 and makes the recesses land on the layer 112.

In an example, the first etch process of 416 may use relatively harsher or aggressive etch chemistry, as this etch process has to traverse through the relatively greater thickness w4 of the dielectric material 120. In contrast, the second etch process of 420 may use relatively gentler etch chemistry, as this etch process has to traverse through only the relatively smaller thickness w2 of the etch stop layer 116. Because the second etch process of 420 uses relatively gentler etch chemistry, the second etch process of 420 may not substantially damage the layer 112, when the recesses 524a, 524b land on the layer 112.

In an example, during formation of the recesses 524a, 524b, there is a possibility of the layer 112 being damaged. Due to scaling of TFT architecture, the thickness w1 of the layer 112 is relatively less (e.g., is in the range of 5-25 nm, or in subranges described herein above). As the thickness w1 is relatively small, even slight or minute damage to the layer 112 may adversely affect performance of the structure 100, increasing possibilities of failure of the structure 100. For example, if the etch stop layer 116 is absent and consequently a single etch process is used to form the recesses 524a, 524b (e.g., as opposed to the two etch processes discussed with respect to 416 and 420, respectively, of FIG. 4), the single etch process has to traverse through the entire thickness w4 of the dielectric material 120. Accordingly, a harsher or aggressive etch process has to be used to traverse through the entire thickness w4 of the dielectric material 120, and this may damage the layer 112 when the recesses 524a, 524b land on the layer 112.

In contrast, method 400 utilizes two distinct etch processes, such as (i) the relatively aggressive or harsher first etch process of 416 that forms the recesses extending through the dielectric material 120, and (ii) the relatively gentle second etch process of 420 that extends the recesses through the etch stop layer 116 and makes the recesses land on the layer 112. Because the second etch process of 420 for landing on the layer 112 is relatively gentle, the second etch process of 420 makes no damage (or less damage than the above discussed single etch process) to the layer 112. Thus, the etch stop layer 116 facilitates in implementing the two distinct etch processes (e.g., as the first etch process of 416 stops at the etch stop layer 116), thereby preventing or at least reducing possibilities of damages to the layer 112 during formation of the recesses 524a, 524b of FIGS. 5D and 5E.

In an example, different etch chemistry (e.g., different etchants) may be used for the first and second etch processes. As an example, one of the first or second etch processes may use a dry etch process, and the other of the first or second etch processes may use a wet etch process. In another example, both first and second etch processes may use dry etch processes, or wet etch processes.

In an example, by controlling the type of the etch process, by controlling the etchants used, and/or by controlling various etch chamber parameters, the first etch process of 416 may be made more harsh or aggressive than the second etch process of 420. In an example, the relatively harsh or aggressive first etch process of 416 uses a plasma etch process, with chlorine plasma as an etchant, at about 1 Millitorr (mTorr) pressure, with oxygen flow at a rate of about 5 standard cubic centimeters per minute (SCCM). The relatively gentle second etch process of 420 may use an atomic layer etching (ALE) type plasma etch, with trimethyl aluminum as etchant, and at about 250 degree centigrade temperature. In an example, using ALE for the second etch process 420 makes the second etch process 420 relatively “gentle” than the first etch process 416. For example, ALE is used to etch one or more top atomic layers of a given body that is to be etched. Hence, ALE can be used to etch the relatively shallow depth etch stop layer 116, and may not substantially damage the layer 112. However, in an example, the plasma etch process may be relatively harsher and may be suitable for the high thickness of the dielectric material 120, and may be used as the first etch process of 416. Other examples of the first etch process of 416 and the second etch process of 420 may also be possible.

Although not illustrated in FIG. 4, subsequent to processes 416 and 420, a further process may be employed that etches out residues from the recesses 524a, 524b, e.g., to clean the recesses 524a, 524b from any remnants of the etch processes 416 and 420 described above.

Referring again to the method 400 of FIG. 4, the method 400 then proceeds from 420 to 424. At 424, source or drain terminals 124a, 124b are formed within the extended recesses 524a, 524b, respectively, such that the source or drain terminals 124a, 124b extend though the etch stop layer 116 and makes contact with the layer 112, e.g., as illustrated in FIG. 5F. For example, conductive material (such as one or more metals or alloys thereof) are deposited within the recesses 524a, 524b, to form the source or drain terminals 124a, 124b. This completes formation of the structure 100 of FIGS. 1A and 5F.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

### Example System

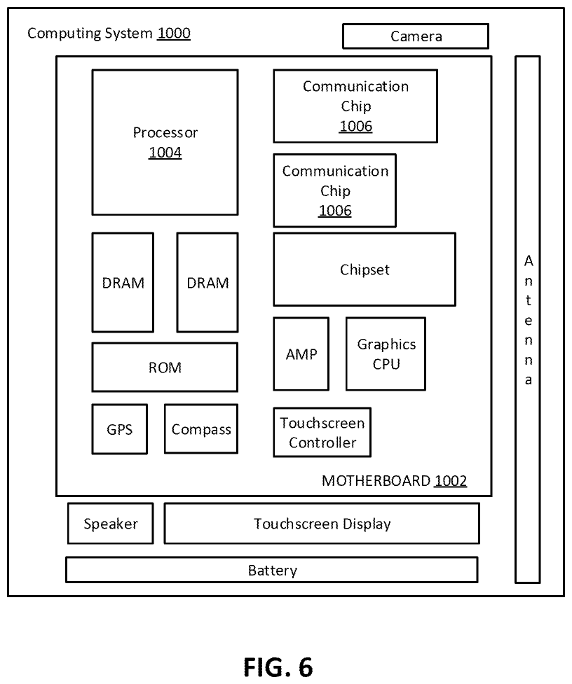

FIG. 6 illustrates a computing system 1000 implemented with integrated circuit structures (such as the integrated circuit structures illustrated in FIGS. 1-3) formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit structure, comprising: a first layer comprising a semiconductor material; a second layer above the first layer, the second layer comprising a metal and one of oxygen or nitrogen, wherein the second layer has a thickness of at most 20 nanometers (nm); and a first source or drain terminal and a second source or drain terminal, each of the first and second source or drain terminals extends through the second layer and is landed on the first layer.

Example 2. The integrated circuit structure of example 1, wherein the second layer is an etch stop layer.

Example 3. The integrated circuit structure of any one of examples 1-2, wherein the second layer comprises aluminum and oxygen.

Example 4. The integrated circuit structure of any one of examples 1-3, further comprising: a dielectric material above the second layer, wherein the dielectric material is elementally and/or compositionally different from the second layer.

Example 5. The integrated circuit structure of example 4, wherein the dielectric material is etch selective with respect to the second layer, such that an etch process to etch the dielectric material doesn't substantially etch the second layer.

Example 6. The integrated circuit structure of any one of examples 4-5, wherein the dielectric material has a thickness of at least 25 nm, and wherein the thicknesses of the dielectric material and the second layer are measured in a direction perpendicular to a length of the first layer.

Example 7. The integrated circuit structure of any one of examples 1-6, further comprising: a gate structure comprising (i) a gate electrode and (ii) a gate dielectric material that separates the first layer from the gate electrode.

Example 8. The integrated circuit structure of example 7, wherein the first layer is above the gate structure.

Example 9. The integrated circuit structure of any one of examples 7-8, wherein the first layer is below the gate structure.

Example 10. The integrated circuit structure of any one of examples 1-9, wherein the first layer has a thickness in a range of 5-25 nm, and wherein the thicknesses of the first layer and the second layer are measured in a direction perpendicular to a length of the first layer.

Example 11. The integrated circuit structure of any one of examples 1-10, wherein the integrated circuit structure is a thin film transistor (TFT) structure, with the first layer being a thin film oxide semiconductor layer of the TFT.

Example 12. The integrated circuit structure of any one of examples 1-11, wherein the semiconductor material of the first layer comprises an oxide semiconductor material.

Example 13. The integrated circuit structure of any one of examples 1-12, wherein the first source or drain terminal and the second source or drain terminal are each multilayer structures.

Example 14. The integrated circuit structure of any one of examples 1-13, wherein the first source or drain terminal and the second source or drain terminal each include a first layer and a second layer.

Example 15. A thin film transistor (TFT) structure, comprising: a layer comprising a metal and oxygen; an etch stop layer on the layer comprising the metal and oxygen; a dielectric material above the etch stop layer later; and a source terminal and a drain terminal, each of the source and drain terminals extending through the dielectric material and the etch stop layer and in contact with the layer comprising the metal and oxygen.

Example 16. The TFT structure of example 15, further comprising: a gate electrode below the layer comprising the metal and oxygen; and a gate dielectric material between the gate electrode and the layer comprising the metal and oxygen.

Example 17. The TFT structure of any one of examples 15-16, wherein the etch stop layer is etch selective to the dielectric material, such that an etch process through the dielectric material doesn't substantially etch the etch stop layer.

Example 18. The TFT structure of any one of examples 15-17, wherein the etch stop layer comprises aluminum and oxygen.

Example 19. The TFT structure of any one of examples 15-18, wherein the etch stop layer is elementally and/or compositionally different from the dielectric material.

Example 20. A method of forming an integrated circuit structure, the method comprising: forming a layer comprising a semiconductor material; forming an etch stop layer above the layer; providing dielectric material above the etch stop layer; forming, using a first etch process, a recess that extends through the dielectric material, wherein the etch stop layer acts to stop the first etch process; extending, using a second etch process, the recess, such that the recess extends though the etch stop layer and contacts the layer comprising the semiconductor material; and forming a source or drain terminal within the recess that extends though the etch stop layer and contacts the layer comprising the semiconductor material.

Example 21. The method of example 20, wherein one or more etchants used for the first etch process are different from other one or more etchants used for the second etch process.

Example 22. The method of any one of examples 20-21, wherein the recess is a first recess, the source or drain terminal is a first source or drain terminal, and the first source or drain contacts a first section of the layer, and wherein the method further comprises: forming, using the first etch process, a second recess that extends through the dielectric material, the second recess separated from the first recess by the dielectric material; extending, using the second etch process, the second recess, such that the second recess extends though the etch stop layer and contacts a second section of the layer; and forming a second source or drain terminal within the second recess that extends though the etch stop layer and contacts the second section of the layer.

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit structure, comprising:
a first layer comprising a semiconductor material;
a second layer above the first layer, the second layer comprising a metal and one of oxygen or nitrogen, wherein the second layer has a thickness of at most 20 nanometers (nm); and
a first source or drain terminal and a second source or drain terminal, each of the first and second source or drain terminals extends through the second layer and is landed on the first layer.

2. The integrated circuit structure of claim 1, wherein the second layer is an etch stop layer.

3. The integrated circuit structure of claim 1, wherein the second layer comprises aluminum and oxygen.

4. The integrated circuit structure of claim 1, further comprising:
a dielectric material above the second layer, wherein the dielectric material is elementally and/or compositionally different from the second layer.

5. The integrated circuit structure of claim 4, wherein the dielectric material is etch selective with respect to the second layer, such that an etch process to etch the dielectric material doesn't substantially etch the second layer.

6. The integrated circuit structure of claim 4, wherein the dielectric material has a thickness of at least 25 nm, and wherein the thicknesses of the dielectric material and the second layer are measured in a direction perpendicular to a length of the first layer.

7. The integrated circuit structure of claim 1, further comprising:
a gate structure comprising (i) a gate electrode and (ii) a gate dielectric material that separates the first layer from the gate electrode.

8. The integrated circuit structure of claim 7, wherein the first layer is above the gate structure.

9. The integrated circuit structure of claim 7, wherein the first layer is below the gate structure.

10. The integrated circuit structure of claim 1, wherein the first layer has a thickness in a range of 5-25 nm, and wherein the thicknesses of the first layer and the second layer are measured in a direction perpendicular to a length of the first layer.

11. The integrated circuit structure of claim 1, wherein the integrated circuit structure is a thin film transistor (TFT) structure, with the first layer being a thin film oxide semiconductor layer of the TFT.

12. The integrated circuit structure of claim 1, wherein the semiconductor material of the first layer comprises an oxide semiconductor material.

13. The integrated circuit structure of claim 1, wherein the first source or drain terminal and the second source or drain terminal are each multilayer structures.

14. A thin film transistor (TFT) structure, comprising:
a layer comprising a metal and oxygen;
an etch stop layer on the layer comprising the metal and oxygen;
a dielectric material above the etch stop layer later; and
a source terminal and a drain terminal, each of the source and drain terminals extending through the dielectric material and the etch stop layer and in contact with the layer comprising the metal and oxygen.

15. The TFT structure of claim 14, further comprising:
a gate electrode below the layer comprising the metal and oxygen; and
a gate dielectric material between the gate electrode and the layer comprising the metal and oxygen.

16. The TFT structure of claim 14, wherein the etch stop layer is etch selective to the dielectric material, such that an etch process through the dielectric material doesn't substantially etch the etch stop layer.

17. The TFT structure of claim 14, wherein the etch stop layer comprises aluminum and oxygen.

18. A method of forming an integrated circuit structure, the method comprising:
forming a layer comprising a semiconductor material;
forming an etch stop layer above the layer;
providing dielectric material above the etch stop layer;
forming, using a first etch process, a recess that extends through the dielectric material, wherein the etch stop layer acts to stop the first etch process;
extending, using a second etch process, the recess, such that the recess extends though the etch stop layer and contacts the layer comprising the semiconductor material; and
forming a source or drain terminal within the recess that extends though the etch stop layer and contacts the layer comprising the semiconductor material.

19. The method of claim 18, wherein one or more etchants used for the first etch process are different from other one or more etchants used for the second etch process.

20. The method of claim 18, wherein the recess is a first recess, the source or drain terminal is a first source or drain terminal, and the first source or drain contacts a first section of the layer, and wherein the method further comprises:
forming, using the first etch process, a second recess that extends through the dielectric material, the second recess separated from the first recess by the dielectric material;
extending, using the second etch process, the second recess, such that the second recess extends though the etch stop layer and contacts a second section of the layer; and
forming a second source or drain terminal within the second recess that extends though the etch stop layer and contacts the second section of the layer.
